(19) United States
(12) Patent Application Publication
(10) Pub. No.: US 2016/0284924 A1
(43) Pub. Date: Sep. 29, 2016

(54) SOLAR CELL AND METHOD FOR MANUFACTURING SUCH A SOLAR CELL

(71) Applicant: STICHTING ENERGIEONDERZOEK CENTRUM NEDERLAND, Petten (NL)

(72) Inventors: Paula Catharina Petronella BRONSVELD, Petten (NL); Lambert Johan GEERLIGS, Petten (NL); Maciej STODOLNY, Petten (NL); Yu WU, Petten (NL)

(73) Assignee: STICHTING ENERGIEONDERZOEK CENTRUM NEDERLAND, Petten (NL)

(21) Appl. No.: 14/778,510

(22) PCT Filed: Mar. 21, 2014
(86) PCT No.: PCT/NL2014/050174

§ 371 Date: Sep. 18, 2015

(30) Foreign Application Priority Data
Mar. 21, 2013 (NL) 2010496

(51) Int. Cl. H01L 31/18; H01L 31/0224; H01L 31/0368; H01L 31/0376; H01L 31/028; H01L 31/0352

(52) U.S. Cl. CPC H01L 31/1804; H01L 31/028; H01L 31/035272; H01L 31/03682; H01L 31/03762; H01L 31/022425

(57) ABSTRACT

A solar cell including a semiconductor substrate, having a front side surface for receiving radiation and back-side surface providing a first junction structure in a first area substrate portion and with a second junction structure in a second area substrate portion. The second area portion borders the first area portion. The first junction structure includes a first conductivity type semiconductor layer covering the first area portion. The second junction structure includes a second conductivity type semiconductor layer covering the second area portion. The second junction structure, second conductivity type semiconductor layer partially overlaps the first junction structure, first conductivity type semiconductor layer, with the overlapping second conductivity type semiconductor layer portion being above a first conductivity type semiconductor layer portion while separated by a first dielectric layer. The first conductivity type semiconductor layer portion under the overlapping second conductivity type semiconductor layer portion directly contacts the semiconductor substrate surface.

### FIELD OF THE INVENTION

The present invention relates to a solar cell. Also, the present invention relates to a method for manufacturing such a solar cell.

### BACKGROUND

Solar cells with back-side contacts are known in the art. In such solar cells the contact layers have been arranged virtually completely on the back-side of the solar cell substrate. In this manner, the area of the front-side of the solar cell that can collect radiative energy can be maximized.

On the back-side, contact structures are used to collect photogenerated charge carriers entirely from the back of the cell.

Such contact structures may comprise p-type and n-type heterostructure junctions (heterojunctions) that are interdigitated.

Solar cells of this type are for example known from US 2008/0061293 that discloses a semiconductor device with heterojunctions and an inter-finger structure. Such a semiconductor device includes, on at least one surface of a crystalline semiconductor substrate, at least one first amorphous semiconductor region doped with a first type of conductivity. The semiconductor substrate includes, on the same at least one surface, at least one second amorphous semiconductor region doped with a second type of conductivity, opposite the first type of conductivity. The first amorphous semiconductor region, which is insulated from the second amorphous semiconductor region by at least one dielectric region in contact with the semiconductor substrate, and the second amorphous semiconductor region form an interdigitated structure.

A disadvantage of such a semiconductor device is that the dielectric region does not collect photo-generated carriers. In addition, the dielectric region needs to passivate the surface very well. Moreover, the fabrication of such a patterned dielectric region requires additional process steps which increase the cost of the solar cell.

Furthermore, in case the semiconductor layers comprise amorphous silicon, deposition of a passivating dielectric layer would commonly be restricted to be before deposition of the semiconductor layers, because deposition of most passivating dielectrics is performed at relatively high substrate temperatures which will deteriorate the passivation created by amorphous silicon layers. This sequence of depositions implies that the dielectric has to be removed on the surface portions where the semiconductor layers will be deposited, which adds an additional risk of surface damage or contamination, and therefore a loss of solar cell quality.

WO 2012/014960 A1 discloses a process for production of a back contact solar cell wherein a second semiconductor layer is formed to cover a first principle surface. A portion of the second semiconductor layer located on a insulating layer is partially removed by etching using a first etchant whose etching rate is higher for the second semiconductor layer than for the insulating layer. A portion of the insulating layer is removed by etching from above the second semiconductor layer using a second etchant whose etching rate for the insulating layer is higher than that for the second semi-conductor layer, thereby exposing a first semiconductor region. Moreover, WO2012/014960 discloses “a semiconducting layer located under insulating layer is used as n-type amorphous semiconductor layer. Then p-side electrode is formed substantially entirely on p-type amorphous semiconductor layer. For this reason, holes which are minority carriers can be easily collected to p-side electrode.”

It is an object of the present invention to provide a solar cell and a method for manufacturing such solar cell that overcome the disadvantages of the prior art.

### SUMMARY OF THE INVENTION

The object is achieved by a solar cell comprising a semiconductor substrate, the semiconductor substrate having a front side surface for receiving radiation and a back-side surface provided with a first junction structure in a first area portion of the substrate and with a second junction structure in a second area portion of the substrate; the second area portion bordering on the first area portion;

the first junction structure comprising a first conductivity type semiconductor layer covering the first area portion;

the second junction structure comprising a second conductivity type semiconductor layer covering the second area portion;

the second conductivity type semiconductor layer of the second junction structure partially overlapping the first conductivity type semiconductor layer of the first junction structure,

the overlapping portion of the second conductivity type semiconductor layer being above a portion of the first conductivity type semiconductor layer while separated by a first dielectric layer therebetween, and

the portion of the first conductivity type semiconductor layer under the overlapping portion of the second conductivity type semiconductor layer is in direct contact with the semiconductor surface of the substrate,

wherein the second conductivity type semiconductor layer in the second area portion borders on the first conductivity type semiconductor layer in the first area portion, adjacent to the overlapping portions of the first and second conductivity type semiconductor layers.

Direct contact in this context means that a surface of the portion of the first conductivity type semiconductor layer is on the substrate surface of the semiconductor without an electrically insulating layer in between.

Bordering or immediate bordering means in this context that the second area portion is adjacent to or is in closest approach or abuts the first area portion without an intermediate dielectric material between the two area portions.

Advantageously, the invention provides that due to the immediate bordering, the collecting areas for the photo-generated charge carriers are maximized without gaps in-between the first and second junction structures. Moreover, by allowing only first and second conductivity type semiconductor layers on the semiconductor of the substrate and excluding first dielectric layers on the substrate in between the first and second junction areas, a better passivation can be achieved which reduces recombination effects and improves the solar cell's efficiency. Furthermore, in case the semiconductor layers comprise amorphous silicon, deposition of a passivating dielectric layer would commonly be restricted to be before deposition of the semiconductor layers, because deposition of most passivating dielectrics is performed at relatively high substrate temperatures which will deteriorate the passivation by amorphous silicon layers. This sequence of depositions implies that the dielectric has to be removed on the surface portions where the semiconductor layers will be deposited, which adds an additional risk of surface damage or contamination, and therefore a loss of solar cell quality. The present invention does not require the use of surface-passivating dielectrics, and therefore allows more flexibility in the choice of material and deposition temperature for dielectric layers.

The invention allows a very useful manufacturing tolerance in the definition of the first and second area portions. Although solar cells could be manufactured according to the present invention using any feasible high pattern definition accuracies, the invention allows also to make solar cells with pattern definition accuracies for example worse than 10 micron, or with even less accuracy. In comparison, for prior art solar cell manufacturing such low accuracies could easily result in loss of cell efficiency, for example because of causing shunt, or increasing series resistance, or leaving substrate area unpassivated.

The invention allows that in addition to substantially fully covering the surface with semiconductor layers, the dielectric layers can be used for pattern definition as masking layer or stopping layer during etching and for isolation. This dual function reduces cost and saves processing steps.

In an aspect the invention relates to a solar cell as described above, wherein the first junction structure comprises a first tunnel barrier layer, the first tunnel barrier layer arranged between the first conductivity type semiconductor layer and the substrate, and/or wherein the second junction structure comprises a second tunnel barrier layer, the second tunnel barrier layer arranged between the second conductivity type semiconductor layer and the substrate.

In an aspect the invention relates to a solar cell as described above, wherein at least one of the first junction structure and the second junction structure comprises an epitaxial Si layer, the first conductivity type semiconductor layer being the epitaxial Si layer and/or the second conductivity type semiconductor layer being the epitaxial Si layer.

In an aspect the invention relates to a solar cell as described above, wherein the interface of the overlapped portion of the first conductivity type semiconductor layer and the substrate surface is void of a dielectric layer.

In an aspect the invention relates to a solar cell as described above, wherein the first conductivity type is p-type, the first conductivity type semiconductor layer comprises p-type doped amorphous hydrogenated silicon, p+a-Si:H, and the first dielectric layer comprises hydrogenated silicon nitride, SiNx:H.

In an aspect the invention relates to a solar cell as described above, wherein the first junction structure comprises an additional first conductive layer or layer stack on top of the first conductivity type semiconductor layer.

In an aspect the invention relates to a solar cell as described above, wherein either the additional first conductive layer is a metallic layer, or the layer stack comprises a conductive oxide layer and an amorphous semiconductor layer, the amorphous semiconductor layer being arranged on top of the stack of the conductive oxide layer and the first conductivity type semiconductor layer.

In an aspect the invention relates to a solar cell as described above, wherein the second junction structure comprises an additional second conductive layer or layer stack, on top of the second conductivity type semiconductor layer.

In an aspect the invention relates to a solar cell as described above, wherein either the additional second conductive layer is a metallic layer, or the layer stack comprises a conductive oxide layer and an amorphous semiconductor layer, the amorphous semiconductor layer being arranged on top of the stack of the conductive oxide layer and the second conductivity type semiconductor layer.

In an aspect the invention relates to a solar cell as described above, wherein the first conductivity type semiconductor layer material comprises an intrinsic amorphous silicon layer or tunnel barrier layer, and a doped layer; the doped layer being one selected from a group comprising a first type doped amorphous silicon, a first type doped silicon-carbon mixture, a first type doped silicon-germanium alloy, first type doped epitaxially grown crystalline silicon, a first type doped poly-silicon.

In an aspect the invention relates to a solar cell as described above, wherein the second conductivity type semiconductor layer material is one selected from a group comprising a second type doped amorphous silicon, a second type doped silicon-carbon mixture, a second type doped silicon-germanium alloy, second type doped epitaxially grown crystalline silicon; a second type doped poly-silicon, and another semiconductor.

In an aspect the invention relates to a solar cell as described above, wherein the first dielectric layer material is one selected from a group comprising silicon nitride, silicon dioxide, silicon oxynitride, a dielectric organic compound, a dielectric metal oxide or dielectric metal nitride.

In an aspect the invention relates to a solar cell as described above, wherein the first junction structure comprises a first tunnel barrier layer, the first tunnel barrier layer arranged between the first conductivity type semiconductor layer and the substrate, and/or wherein the second junction structure comprises a second tunnel barrier layer, the second tunnel barrier layer arranged between the second conductivity type semiconductor layer and the substrate.

Additionally, the present invention relates to a method for manufacturing a solar cell from a semiconductor substrate, the semiconductor substrate having a front side surface for receiving radiation and a back-side surface provided with a first junction structure in a first area portion of the substrate and with a second junction structure in a second area portion of the substrate, the second area portion bordering on the first area portion; the method comprising:

depositing on the back-side surface of the substrate over at least the first area portion a first conductivity type semiconductor layer; optionally depositing conducting layers;

depositing a first dielectric layer over at least the first conductivity type semiconductor layer; patterning the first dielectric layer for defining the first area portion by covering the first conductivity type semiconductor layer in the first area portion and for exposing the second area portion; patterning the first conductivity type semiconductor layer using the patterned first dielectric layer as mask to create the first junction structure in the first area portion and to expose the surface of the silicon substrate in the second area portion; depositing on the back-side surface, a second conductivity type semiconductor layer over at least part of the first dielectric layer bordering the second area portion, and the exposed second area portion, in such a manner that the second conductivity type semiconductor layer of the second junction structure partially overlaps the first conductivity type semiconductor layer of the first junction structure, the overlapping portion of the second conductivity type semiconductor layer being above a portion of the first conductivity type semiconductor layer while separated by a first dielectric layer therebetween, and the portion of the first conductivity type semiconductor layer under the overlapping portion of the second conductivity type semiconductor layer is in direct contact with the semiconductor surface of the substrate.

In case the optionally deposited conducting layer is a conductive oxide, in the following the dielectric layer maybe replaced by an intrinsic amorphous silicon layer.

The first conductivity type can be equal to or opposite to the conductivity type of the semiconductor substrate.

The method according to the present invention allows a self-aligned formation of edges of the first conductivity type layer with edges of the first dielectric layer, maximizing the substrate area covered with active (first or second conductivity type semiconductor layers) while improving isolation between the two semiconductor layers.

Furthermore, the method advantageously allows that the first dielectric layer functions both for separation of the first and second conductivity type semiconductor layers, as well as for covering the first conductivity type semiconductor layer during the deposition of the second conductivity type semiconductor layer. The covering can protect against the thermal degradation of the passivation by the first conductivity type semiconductor layer during the deposition of the second conductivity type semiconductor layer. This degradation is known to occur in a p-type doped a-Si:H layer during deposition of an n-type doped a-Si:H layer.

According to an aspect, the method further provides a step of depositing a masking layer over the second conductivity type semiconductor layer that at least covers the second area portion and (the bordering) part of the first area portion, which is followed by patterning the masking layer; and using the patterned masking layer for locally removing the second conductivity type semiconductor layer.

Alternatively, the second conductivity type semiconductor layer can be etched by a direct method, e.g. by printing an etching paste in the required pattern.

Optionally, the first dielectric layer can be removed with the second conductivity type semiconductor layer as a mask. This will give a self-alignment of these layers. Advantageously, the method thus allows a self-aligned formation of the edges of the first and second conductivity type layers with the edges of the first dielectric layer, maximizing the areas of first and second conductivity type semiconductor layers exposed for applying a metallization layer, while ensuring isolation between the two.

In an aspect the method as described above further comprises: depositing a masking layer over the second conductivity type semiconductor layer at least covering the second area portion and part of the first area portion; patterning the masking layer; patterning the second conductivity type semiconductor layer using the patterned masking layer as mask to create the second junction structure in the second area portion with a pattern that provides the second conductivity type semiconductor layer to border on and partially overlap the first conductivity type semiconductor layer, the overlapping portion of the second conductivity type semiconductor layer being on top of the first conductivity type semiconductor layer, separated by the first dielectric layer.

According to an aspect the method as described above provides that the first junction structure is provided with a first tunnel barrier layer, the first tunnel barrier layer arranged between the first conductivity type semiconductor layer and the substrate, and/or wherein the second junction structure is provided with a second tunnel barrier layer, the second tunnel barrier layer arranged between the second conductivity type semiconductor layer and the substrate.

In an aspect the method as described above provides that at least one of the first junction structure and the second junction structure comprises an epitaxial Si layer, the first conductivity type semiconductor layer being the epitaxial Si layer and the substrate, and/or the second conductivity type semiconductor layer being the epitaxial Si layer.

In an aspect the method as described above provides that the first conductivity type is p-type, the first conductivity type semiconductor layer comprises p-type doped amorphous hydrogenated silicon, p+a-Si: and the first dielectric layer comprises hydrogenated silicon nitride, SiNx:H, the p+a-Si:H layer being covered by the SiNx:H layer.

Advantageous embodiments are further defined by the dependent claims.

### BRIEF DESCRIPTION OF DRAWINGS

The invention will be explained in more detail below with reference to a few drawings in which illustrative embodiments thereof are shown. They are intended exclusively for illustrative purposes and not to restrict the inventive concept, which is defined by the claims.

In the drawings,

FIGS. 1a-1c show a cross-section of a solar cell after a first manufacturing step;

FIG. 2 shows a cross-section of a solar cell after a next manufacturing step;

FIG. 3 shows a cross-section of a solar cell semiconductor substrate after an initial patterning step;

FIG. 4 shows a cross-section of a solar cell semiconductor substrate after completion of the patterning step of the first semiconductor layer;

FIGS. 5a and 5b show a cross-section of a solar cell after a next manufacturing step;

FIG. 6 shows a cross-section of a solar cell after a deposition of a masking layer;

FIG. 7 shows a cross-section of a solar cell after a subsequent patterning step;

FIG. 8 shows a cross-section of a solar cell after a etching step;

FIG. 9a-9c shows a cross-section of a solar cell after a next manufacturing step;

FIG. 10a-10e show a cross-section of a solar cell after a metallisation step;

FIG. 11a-11c show a cross-section of a solar cell according to an alternative embodiment;

FIG. 12 shows a cross-section of a solar cell according to an alternative embodiment after a next manufacturing step;

FIG. 13 shows a cross-section of a solar cell after a removal of a second masking layer and

FIG. 14 shows a cross-section of a solar cell after a subsequent manufacturing step.

### DESCRIPTION OF EMBODIMENTS

In the following Figures, the same reference numerals refer to similar or identical components in each of the Figures. The solar cell comprises a semiconductor substrate, typically a silicon wafer.

Such a wafer may be either polycrystalline or monocrystalline.

The wafer may be textured on at least the front, and it may be provided with a front side passivation by, for example, a front diffused layer and a front passivating coating. It may also be provided with an antireflection coating on the front. The front side texture and coating may also be provided later during the process. The front side may also be provided with sacrificial layers, protecting against some of the processes described below.

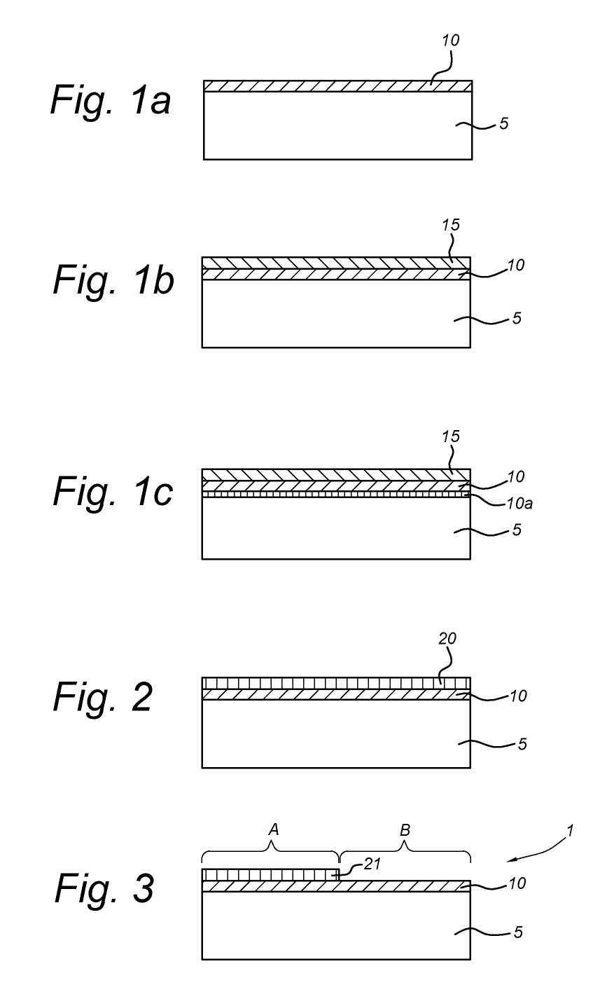

FIG. 1a shows a cross-section of the semiconductor substrate 5 after a first processing step in a manufacturing sequence. In this step a first conductivity type semiconductor layer 10 is deposited over at least a first portion of the surface of the substrate 5. The first conductivity type semiconductor layer will form a first junction with the semiconductor substrate surface.

The first conductivity type semiconductor layer material can be selected from a group comprising a first type doped amorphous hydrogen-enriched silicon (a-Si:H), a first type doped microcrystalline silicon, a first type doped amorphous silicon-carbon mixture, a first type doped silicon-germanium alloy, a first type doped epitaxially grown crystalline silicon, first type doped poly-silicon, or other semiconductor. Additionally, the first conductivity type semiconductor layer may comprise a stack of an intrinsic semiconductor layer and a first type doped semiconductor layer, with materials selected as described above, such as a heterojunction with an intrinsic thin layer (HIT structure), as known in the state of the art.

The first conductivity type layer may also comprise a surface layer of the substrate, created by diffusion or implantation of doping into the substrate, which may be local or followed by an etch-back outside the first area portion A.

The first area portion that is covered is at least equal to the area where the first junction will be created.

Optionally in an embodiment, the first and/or second junctions may comprise metal-insulator- semiconductor (MIS) junctions.

Figure lb shows a cross-section of a semiconductor substrate after the first manufacturing step, in case the first conductivity type semiconductor layer is covered by a conductive layer 15 that functions as collecting layer and/or parallel conductor to improve current extraction and/or current flow. The conductive layer can for example be a metal layer or a (transparent) conductive oxide layer or a combination thereof.

Below the invention will be described with reference to an embodiment of the first conductivity type semiconductor layer without conductive layer. It will be appreciated that in an alternative embodiment instead of a first conductivity type semiconductor layer, a stack of the first conductivity type semiconductor layer 10 with the conductive layer 15 can be used.

It is also noted that as shown in FIG. 1c, in an embodiment, between the surface of the semiconductor substrate 5 and the first conductivity type semiconductor layer 10, a thin tunnel barrier layer 10a may be arranged which layer 10a provides a tunneling contact for charge carriers between the semiconductor substrate 5 and the first conductivity type semi-conductor layer 10.

FIG. 2 shows a cross-section of a solar cell 1 after a next manufacturing step. In a next step, on top of the first conductivity type semiconductor layer, a first dielectric layer 20 is deposited that covers the first conductivity type semiconductor layer at least in the first area portion A.

It is noted that in case the optionally deposited conductive layer is a conductive oxide, instead of the first dielectric layer, an intrinsic amorphous silicon layer may be deposited.

The first dielectric layer material may comprise a material selected from a group comprising silicon nitride, silicon dioxide, silicon-oxy-nitride, a dielectric organic compound (such as a “resist” or a resin), a dielectric metal oxide or dielectric metal nitride, and other suitable dielectrics.

In case the stack in FIG. 1a 1b or 1c ends with a conductive oxide as top layer, it can be beneficial for the choice of available etchants to replace the dielectric layer by an intrinsic amorphous silicon layer.

FIG. 3 shows a cross-section of the semiconductor substrate after a patterning step of the first dielectric layer. This patterning removes the first dielectric layer from the second area portion B of the semiconductor substrate where a second junction is to be created. In the first area portion A where the first junction is to be created, the patterned first dielectric layer 21 is maintained. According to an aspect of the invention, the first area portion A borders on, is adjacent to, the second area portion B of the semiconductor substrate.

By the patterning step an interdigitated structure can be defined in which first type junctions are interdigitated with second type junctions.

The patterning step comprises an etching step, which may be a selective etching step, to remove the first dielectric layer and to expose the first conductivity type semiconductor layer in the areas where the first dielectric layer is removed.

The patterned first dielectric layer 21 serves as a mask for creating a patterned first conductivity type semiconductor layer 11. The exposed first conductivity type semiconductor layer is removed from the second area portion B of the semiconductor substrate using an etching step, which may be a selective etching step.

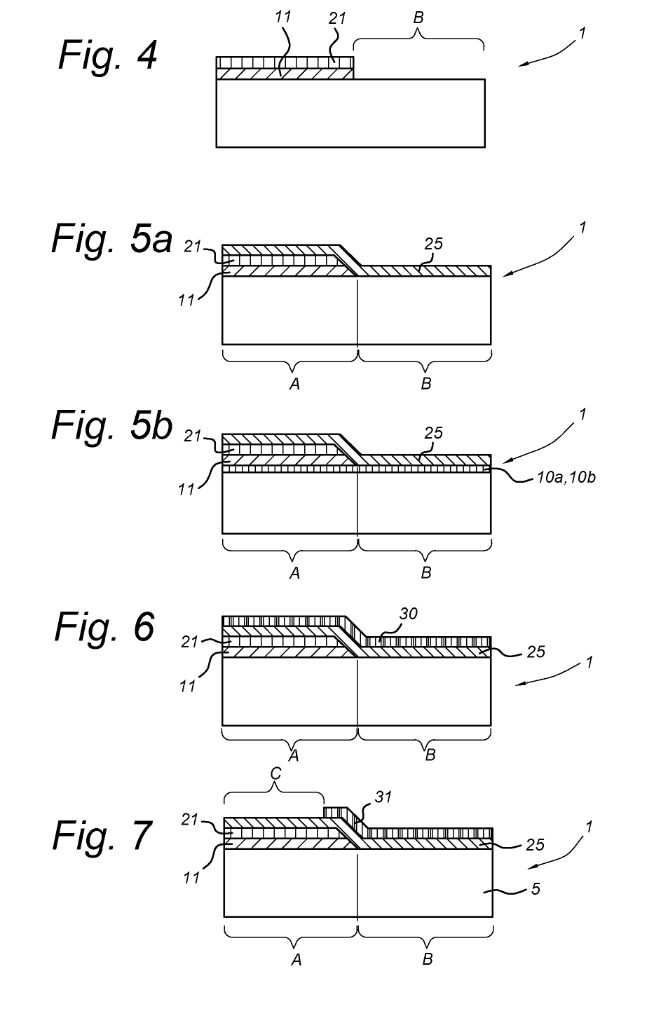

The patterning of the first conductivity type semiconductor layer is schematically shown in FIG. 4. Because the pattern of the first dielectric layer is transferred into the pattern of the first conductivity type layer, the edges of the patterns of the two layers are substantially self-aligned. Such self-alignment has advantages of reducing the number of process steps, reducing the required alignment tolerances, and reducing costs.

FIG. 5a shows a cross-section of a solar cell after a subsequent step. On the patterned surface a second conductivity type semiconductor layer 25 is deposited over at least the second area portion B of the semiconductor substrate and over at least a bordering portion of the stack of the patterned first dielectric layer 21 and the patterned first conductivity type semiconductor layer 11 which are adjacent to the second area portion B.

In this structure, the patterned first dielectric layer 21 provides insulation between the second conductivity type semiconductor layer 25 overlapping the patterned first conductivity type semiconductor layer 11.

The overlap of the first and second conductivity type semiconductor layers is shown to have a slope. It is noted that the actual slope angle may depend on the actual processing steps and conditions. Also, the slope may be substantially perpendicular to the surface of the substrate, or stepped.

Additionally, the second conductivity type semiconductor layer 25 borders on the patterned first conductivity type semiconductor layer 11.

Because during the etching of the patterned first conductivity type semiconductor layer 11 some undercut (etching of layer 11 under layer 21) may occur, the words “borders on” are intended to define that the lateral distance between the two patterned semiconductor layers 11, 25 is at most a few times the thickness of patterned first conductivity type semiconductor layer 11.

For example if patterned first conductivity type semiconductor layer 11 is 20 nm thick, the bordering of the layers means that they are within about 100 nm or less of each other.

Like the patterned first conductivity type semiconductor layer 11, layer 25 may be covered with an optional conductive layer, such as transparent conductive oxide (TCO) and/or metal.

The second conductivity type semiconductor layer material can be selected from a group comprising a second type doped amorphous silicon, a second type doped silicon-carbon mixture, a second type doped silicon-germanium alloy, second type doped epitaxially grown crystalline silicon, second type doped poly-silicon, or other semiconductor. Additionally, similar as for the first conductivity type semiconductor layer, the second conductivity type semiconductor layer may comprise a stack of an intrinsic semiconductor layer and a second type doped semiconductor layer, with materials selected as described above. Also, similar as for the first conductivity type semiconductor layer, between the surface of the semiconductor substrate 5 and the second conductivity type semiconductor layer, a thin tunnel barrier layer (not shown) may be arranged.

Additionally, the second conductivity type layer may also consist of a layer stack forming a MIS junction.

The second conductivity type is opposite to the first conductivity type. The first conductivity type semiconductor layer may constitute the emitter and the second conductivity type layer the BSF, or the first conductivity type layer may constitute the BSF and the second conductivity type layer the emitter.

In an embodiment, the first conductivity type is p-type and the first conductivity type semiconductor layer is p+a-Si:H, and the first dielectric layer is SiNx:H. Advantageously, the present invention provides that in this configuration the p-type a-Si:H layer is covered by the first dielectric. An exposed p-type a-Si:H layer when bare will degrade during deposition of a subsequent a-Si layer, basically due to thermal exposure. Covering with SiNx:H protects the p-type layer against such degradation, and therefore this invention allows a p-type emitter as first conductivity type semiconductor layer. It may be favorable to start with the p-type layer for cell efficiency reasons since this layer is generally the emitter which occupies generally the largest area on the rear surface.

Additionally, it may be favorable since the process of opening the first conductivity type layer can cause surface damage which diminishes the passivation properties of the layer deposited on the opened area.

FIG. 5b shows a cross-section of a solar cell after a subsequent step as described above in FIG. 5a, for an embodiment in which a tunnel barrier 10a, 10b is present either between the surface of the semiconductor substrate 5 and the patterned first conductivity type semiconductor layer 11, or between the surface of the semiconductor substrate 5 and the patterned second conductivity type semiconductor layer 25, or between the surface of the semiconductor substrate 5 and both the patterned first and second conductivity type semiconductor layers 11, 25.

Each of the tunnel barriers 10a, 10b under the first conductivity type semiconductor layer and second conductivity type semiconductor layer may be formed individually in separate processes. The tunnel barrier layer 10a, 10b may be grown by a surface reaction or may be deposited by a physical or chemical deposition process.

FIG. 6 shows a cross-section of a solar cell according to an embodiment of the invention, after a further step, in which a masking layer 30 is deposited over at least part of the first area portion A and the second area portion B. The masking layer may comprise a material selected from a group comprising silicon nitride (SiNx), silicon dioxide (SiO2), silicon-oxynitride (SiOxNy), a dielectric organic compound (a “resist” or resin), a dielectric metal oxide or dielectric metal nitride, and other suitable dielectrics. The masking layer may also be a metallic (e.g. contacting) layer.

Alternatively, the masking layer may be an intrinsic amorphous silicon layer, depending on the etching properties of the top layer deposited in the preceding process step.

Next a patterning step is carried out as shown in FIG. 7. In the patterning step the masking layer 30 is patterned into a patterned mask 31 by removing the masking layer from a third area portion C of the stack of the patterned first dielectric layer 21 and the patterned first conductivity type semiconductor layer 11.

Alternatively, the masking layer 30 may be deposited in a suitable pattern (pattern of layer 31), e.g. by deposition through a proximity mask, by deposition by a printing technique, etc.

The created third area portion C is smaller than the first area portion A, thus exposing a portion of the second conductivity type semiconductor layer above the stack of the patterned first dielectric layer 21 and the patterned first conductivity type semiconductor layer 11. At the same time dielectric layer 31 covers a further portion of the second conductivity type semiconductor layer 25 that is in overlap with the stack of the patterned first dielectric layer 21 and the first conductivity type semiconductor layer 11.

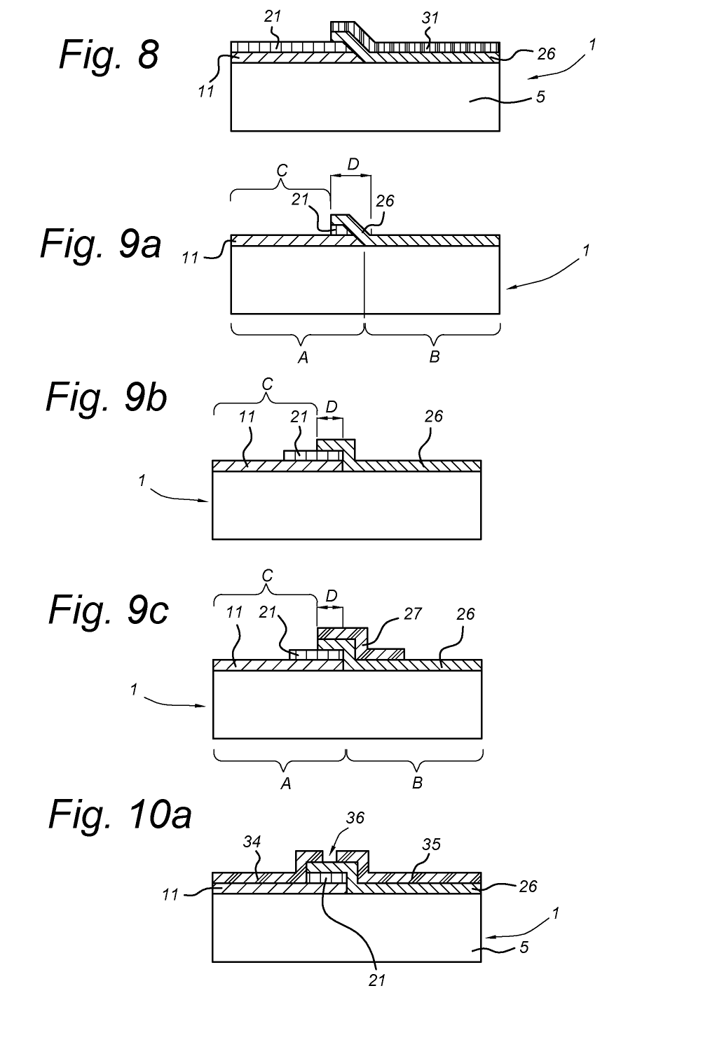

FIG. 8 shows a cross-section of a solar cell after a subsequent etching step, in which the exposed second conductivity type semiconductor layer 25 on the third area portion C is removed using the patterned mask 31 and a patterned second conductivity type semiconductor layer 26 is thus created. During this removal, the first conductivity type layer 11 is protected by the first dielectric layer 21, which acts also as an etch-stop for this second removal.

Alternatively to deposition and patterning of layers 30 and 31 and etching of layer 25, the second conductivity type semiconductor layer 25 may be removed on the third area portion C by a direct etching process, such as printing or (ink)jetting an etchant, or plasma etching through a proximity mask.

The solar cell structure now comprises the first area portion A where a first junction is arranged between the patterned first conductivity type semiconductor layer 11 and the substrate 5 and the second area portion B where a second junction is arranged between the patterned second conductivity type semiconductor layer 26 and the substrate 5. Since on the surface of the semiconductor substrate, the first and second area portions A, B are adjacent to each other, the first and second junctions are also adjacent. In this manner the first and second junctions can be arranged in a closest approach. This bordering arrangement of the junctions provides a substantially complete coverage of the actively used substrate area for collecting charge carriers.

FIGS. 9a-9c show a cross-section of a solar cell according to a respective embodiment after a next step.

In this step, the patterned mask 31 or the patterned second conductivity type semiconductor layer 26 are functioning as a mask used for etching and removing the patterned first dielectric layer 21 in the third area portion C. Mask 31 may be absent in the case that, for example, layer 25 is locally removed by a direct etch process (as described above).

Layer 21 may also be locally removed (in third area portion C or a smaller area portion thereof) in a direct patterning step, e.g. by printing an etching paste (FIG. 9b).

Layer 21 and 31 may also be locally removed by e.g. a wet-chemical etching step while e.g. protecting area D and some adjacent regions on area A and B by a dielectric etch mask, e.g. a deposited resist pattern 27. The resulting structure will then differ from FIG. 9a by having layer 21 extending some length into area A, and layer 31 being present on area D as well as extending some length into area B (FIG. 9c).

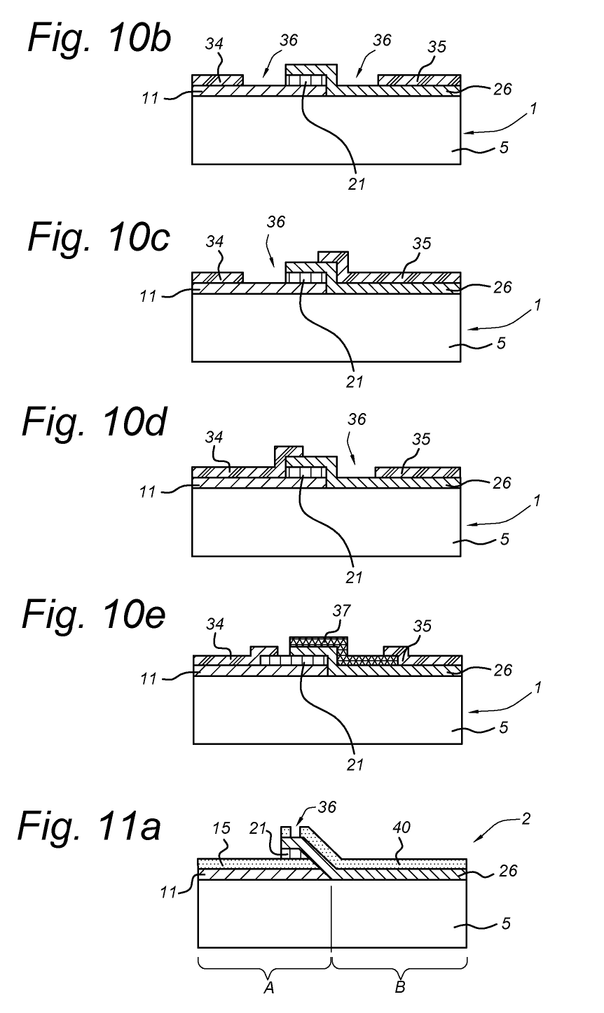

The latter arrangement may be useful for improving long-term stability and improving electrical isolation in the final solar cell (resulting in FIG. 10e).

The patterned mask 31, if present, may be removed in the same etching step that removes layer 21 (in case of comparable etching sensitivity and thickness of the first and second dielectric layer), or a further selective etching step.

After the etching step and the removal of the patterned mask 31, the solar cell structure comprises the first area portion A where a first junction is arranged between the patterned first conductivity type semiconductor layer 11 and the substrate 5 and the second area portion B where a second unction is arranged between the patterned second conductivity type semiconductor layer 26 and the substrate 5. Further the solar cell structure comprises an overlapping portion of the patterned second conductivity type semiconductor layer 26 that overlaps the patterned first conductivity type semiconductor layer. In an overlapping area D, the second conductivity type semiconductor layer 26 is separated and isolated by the patterned first dielectric layer 21. In an example, the width of area D as indicated in FIGS. 9a, 9b, 9c is between about 1 and about 1000 micron. In an alternative example the width of area D is between about 10 and about 500 micron. In yet another example the width of area D is between about 50 and about 250 micron.

Both the patterned first conductivity type semiconductor layer 11 in its first area portion A and the patterned second conductivity type semiconductor layer 26 in its second area portion B are in direct contact with the surface of the substrate over the respective full area portion (or are in contact with the tunnel barrier layer covering the surface of the substrate in case a tunnel barrier layer is present on the surface of the substrate) forming a first and second junction respectively.

Thus first conductivity type semiconductor layer 11 is substantially fully in contact with the substrate.

FIGS. 10-14 show some possible processes for metallization. Metallization may consist of the conductive layers introduced previously, and/or further conductive layers that (additionally) may be applied subsequently.

In FIGS. 10-14 entities with the same reference number as shown in preceding Figures refer to corresponding entities.

FIG. 10a-10e show cross-sections of the solar cell 1 after a metallization step. As shown in FIG. 10a, on top of the patterned first conductivity type semiconductor layer 11 and the patterned second conductivity type semiconductor layer 26 a metallization layer (metallic conductive layer) 34, 35 is deposited. FIGS. 10b-10e shows optional modifications of this step.

The metallization layer 34, 35 is patterned by at least a gap 36 in the metallization layer to created electric isolation between a first portion 34 of the metallization layer over the first junction structure 5, 11 and a second portion 35 of the metallization layer over the second junction structure 5, 26. The gap 36 is at least located above the overlapping portion of the second conductivity type semiconductor layer 26, so that maximum coverage of metal on layer 11 and layer 26 is achieved, and minimum resistive loss, but may also extend further above portion A or B or both.

Extending the gap 36 from the overlapping portion to above either the first portion A or second portion B or both portions A, B may reduce the possibility for shunt, for example, if the dielectric 21 is not completely free of pinholes.

FIG. 10e shows an embodiment where no areas of the patterned first and second conductivity type semiconductor layers 11 and 26 are directly exposed to atmospheric conditions. A dielectric layer 37 which could be the same as dielectric layer 27 as shown in FIG. 9c covers an area of layer 26 adjacent to the overlapping area of the first and second semiconductor layers 11, 26. This arrangement may enhance durability of the performance of the solar cell. The metallization layers 34, 35 may be deposited as blanket and subsequently patterned by etching, or it may be deposited in a pattern immediately.

The metallization layer may also consist of a first blanket deposition (e.g. a conductive oxide and/or a seed metal layer), followed by a patterned deposition of a second metallization layer (e.g. a (screen) printed or inkjetted silver pattern, or a resist pattern followed by (electro)plating), in turn followed by an etch back of the first blanket, using the second metallization pattern as a mask.

In an embodiment, the first blanket deposited layer may also be provided with a metal pattern by coating the first blanket layer with a dielectric layer such as silicon oxide, after which the dielectric layer is patterned and the conductive oxide is electroplated where it is free of the dielectric.

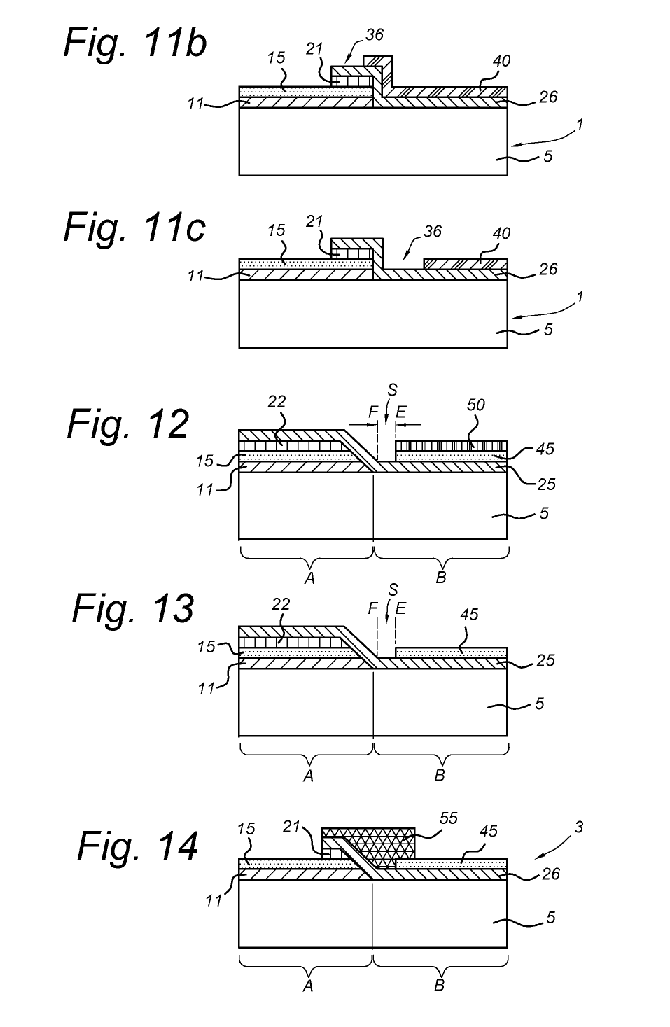

FIG. 11a-11c show a cross-section of a solar cell 2 according to a respective alternative embodiment. The single first conductivity type semiconductor layer is replaced by a first stacked layer that forms the first junction structure on the substrate and comprises the first conductivity type semiconductor layer 11 and the conductive layer 15 on top of it. The stacked arrangement is similar as shown in Figure lb.

The patterned second conductivity type semiconductor layer 26 is covered by a second conductive layer 40 and forms a second stacked layer. Preferably the second conductive layer is patterned in correspondence with the second conductivity type semiconductor layer 26, for example by a process as described above with reference to FIG. 8. In the embodiment as shown in FIG. 11a, the gap 36 above the overlapping portion may be omitted.

The first stacked layer borders on the second stacked layer. The second stacked layer overlaps the first stacked layer in the overlapping region D. In the overlapping region D the first stacked layer is separated from the overlapping second stacked layer by an insulating dielectric layer 21, in a similar manner as shown in FIGS. 5-8.

In case the conductive layer 15 in the first junction structure is a conductive oxide, dielectric layer 21 may be replaced by an intrinsic amorphous semiconductor layer.

FIGS. 11b and 11c show an embodiment in which the gap 36 in the second conductive layer 40 extends over either the overlapping portion D or a part of the second area portion B.

The gap 36 in the second conductive layer 40 may be created around the overlapping portion of the second conductivity type semiconductor layer 26 to improve isolation from the conductive layer 15 in the first junction structure if needed.

It will be appreciated that as mentioned above various sloped forms of the overlapping portion D can be obtained, as indicated by the difference in slope of the overlap of the first and second conductivity type semiconductor layers in FIG. 11a and FIGS. 11b, 11c.

FIG. 12 shows a cross-section of a solar cell according to an alternative embodiment after a manufacturing step.

In this embodiment, the first junction structure in the first area portion A comprises a stack of the first conductivity type semiconductor layer 11 and the conductive layer 15 on top of it. The stack of the first conductivity type semiconductor layer 11 and the conductive layer 15 is patterned and covered by a patterned dielectric layer 22.

Covering the patterned stack of the first conductivity type semiconductor layer 11, the conductive layer 15 and the dielectric layer 22, is the second conductivity type semiconductor layer 25. In the second junction structure in the second area portion B a stack of a patterned second conductive layer 45 and a second masking layer 50 is arranged, with the second masking layer on top of the second conductive layer 45.

To obtain the structure as shown in FIG. 12, both the second conductive layer 45 and the second masking layer 50 are deposited over at least the second area portion B. Next the second masking layer 50 is patterned. The patterned second masking layer 50 is then used to define the location of the patterned second conductive layer 45 in the second area portion B. An optional spacing S between the end E of the patterned second conductive layer 45 and the boundary F of the first area portion A and the second area portion B is created to improve isolation.

FIG. 13 shows a cross-section of the solar cell of FIG. 12 after a next step according to an embodiment wherein the second masking layer 50 is selectively removed. It will be appreciated that removal of the second masking layer 50 may be optional, since a contact to the second conductive layer 45 may be achieved through the second masking layer 50 e.g., by mechanical force.

FIG. 14 shows a cross-section of the solar cell 3 of FIG. 13 after a subsequent manufacturing step. In the subsequent step, a dielectric, e.g. a resist layer is deposited over the structure as shown in FIG. 13. Next, if the dielectric layer was not deposited in a pattern, the dielectric layer is patterned to create a protective dielectric, e.g. a resist, body 55 that covers the overlapping portion of the second conductivity type semiconductor layer and the boundary region E-F between the first and second area portions A, B.

The patterned protective dielectric body is used as a mask to etch/remove a portion of the second conductivity type semiconductor layer 25 and of the dielectric layer 22 using the conductive layer 15 and the second conductive layer 45 as etch stop layers, in a manner that the overlapping portion of the second conductivity type semiconductor layer overlaps the stack of the patterned conductive layer 15 and the patterned first conductivity type semiconductor layer 11. The first dielectric layer 21 acts as a separating layer.

The protective dielectric body 55 can be used in a subsequent plating step (e.g. an electroplating step) to separate a metal contact on the first area portion A from a metal contact on the second area portion B. The protective dielectric body 55 can also provide durability of the performance of the solar cell, by protecting the layer 26 which may be very thin and susceptible to atmospheric conditions penetrating a solar module.

The skilled in the art will appreciate that the protective dielectric body can be applied in other embodiments such as for example the embodiment shown in FIG. 10e.

It will be apparent to the person skilled in the art that other embodiments of the invention can be conceived and reduced to practice without departing from the true spirit of the invention, the scope of the invention being limited only by the appended claims. The above described embodiments are intended to illustrate rather than to limit the invention.

1. A solar cell, comprising a semiconductor substrate, the semiconductor substrate having a front side surface for receiving radiation and a back-side surface provided with a first junction structure in a first area portion of the substrate and with a second junction structure in a second area portion of the substrate;
the second area portion bordering on the first area portion;
the first junction structure comprising a first conductivity type semiconductor layer covering the first area portion;
the second junction structure comprising a second conductivity type semiconductor layer covering the second area portion;
the second conductivity type semiconductor layer of the second junction structure partially overlapping the first conductivity type semiconductor layer of the first junction structure, the overlapping portion of the second conductivity type semiconductor layer being above a portion of the first conductivity type semiconductor layer while separated by a first dielectric layer therebetween, and
the portion of the first conductivity type semiconductor layer under the overlapping portion of the second conductivity type semiconductor layer is in direct contact with the semiconductor surface of the substrate,
wherein the second conductivity type semiconductor layer in the second area portion borders on the first conductivity type semiconductor layer in the first area portion, adjacent to the overlapping portions of the first and second conductivity type semiconductor layers.

2. The solar cell according to claim 1, wherein the first junction structure comprises a first tunnel barrier layer, the first tunnel barrier layer arranged between the first conductivity type semiconductor layer and the substrate, and/or
wherein the second junction structure comprises a second tunnel barrier layer, the second tunnel barrier layer arranged between the second conductivity type semiconductor layer and the substrate.

3. The solar cell according to claim 1, wherein at least one of the first junction structure and the second junction structure comprises an epitaxial Si layer, the first conductivity type semiconductor layer being the epitaxial Si layer and/or the second conductivity type semiconductor layer being the epitaxial Si layer.

4. The solar cell according to claim 1, wherein the interface of the overlapped portion of the first conductivity type semiconductor layer and the substrate surface is void of a dielectric layer.

5. The solar cell according claim 1, wherein the first conductivity type is p-type, the first conductivity type semiconductor layer comprises p-type doped amorphous hydrogenated silicon, p+a-Si:H, and the first dielectric layer comprises hydrogenated silicon nitride, SiNx:H.

6. The solar cell according to claim 1, wherein the first junction structure comprises an additional first conductive layer or layer stack on top of the first conductivity type semiconductor layer.

7. The solar cell according to claim 6, wherein
either the additional first conductive layer is a metallic layer,
or the layer stack comprises a conductive oxide layer and an amorphous semiconductor layer, the amorphous semiconductor layer being arranged on top of the conductive oxide layer and the first conductivity type semiconductor layer.

8. The solar cell according to claim 1, wherein the second junction structure comprises an additional second conductive layer or layer stack, on top of the second conductivity type semiconductor layer.

9. The solar cell according to claim 8, wherein
either the additional second conductive layer is a metallic layer,
or the layer stack comprises a conductive oxide layer and an amorphous semiconductor layer, the amorphous semiconductor layer being arranged on top of the conductive oxide layer and the second conductivity type semiconductor layer.

10. The solar cell according to claim 1, wherein the first conductivity type semiconductor layer material comprises an intrinsic amorphous silicon layer or tunnel barrier layer, and a doped layer; the doped layer being one selected from a group comprising a first type doped amorphous silicon, a first type doped silicon-carbon mixture, a first type doped silicon-germanium alloy, first type doped epitaxially grown crystalline silicon, a first type doped poly-silicon.

11. The solar cell according to claim 1, wherein the second conductivity type semiconductor layer material is one selected from a group comprising a second type doped amorphous silicon, a second type doped silicon-carbon mixture, a second type doped silicon-germanium alloy, second type doped epitaxially grown crystalline silicon; a second type doped poly-silicon, and another semiconductor.

12. The solar cell according to claim 1, wherein the first dielectric layer material is one selected from a group comprising silicon nitride, silicon dioxide, silicon oxynitride, a dielectric organic compound, a dielectric metal oxide or dielectric metal nitride.

13. The solar cell according to claim 1, wherein the first junction structure comprises a first tunnel barrier layer, the first tunnel barrier layer arranged between the first conductivity type semiconductor layer and the substrate,
and/or wherein the second junction structure comprises a second tunnel barrier layer, the second tunnel barrier layer arranged between the second conductivity type semiconductor layer and the substrate.

14. A method for manufacturing a solar cell from a semiconductor substrate,
the semiconductor substrate having a front side surface for receiving radiation and a back-side surface provided with a first junction structure in a first area portion of the substrate and with a second junction structure in a second area portion of the substrate, the second area portion bordering on the first area portion;
the method comprising:
depositing on the back-side surface of the substrate over at least the first area portion a first conductivity type semiconductor layer;
optionally depositing conducting layers;
depositing a first dielectric layer over at least the first conductivity type semiconductor layer
patterning the first dielectric layer for defining the first area portion by covering the first conductivity type semiconductor layer in the first area portion and for exposing the second area portion;
patterning the first conductivity type semiconductor layer using the patterned first dielectric layer as mask to create the first junction structure in the first area portion and to expose the surface of the silicon substrate in the second area portion;
depositing on the back-side surface, a second conductivity type semiconductor layer over at least part of the first dielectric layer bordering the second area portion, and the exposed second area portion,
in such a manner that the second conductivity type semiconductor layer of the second junction structure partially overlaps the first conductivity type semiconductor layer of the first junction structure,
the overlapping portion of the second conductivity type semiconductor layer being above a portion of the first conductivity type semiconductor layer while separated by a first dielectric layer therebetween, and
the portion of the first conductivity type semiconductor layer under the overlapping portion of the second conductivity type semiconductor layer is in direct contact with the semiconductor surface of the substrate.

15. The method according to claim 14, further comprising:
depositing a masking layer over the second conductivity type semiconductor layer at least covering the second area portion and part of the first area portion;
patterning the masking layer;
patterning the second conductivity type semiconductor layer using the patterned masking layer as mask to create the second junction structure in the second area portion with a pattern that provides the second conductivity type semiconductor layer to border on and partially overlap the first conductivity type semiconductor layer,
the overlapping portion of the second conductivity type semiconductor layer being on top of the first conductivity type semiconductor layer, separated by the first dielectric layer.

16. The method according to claim 14, wherein the first junction structure is provided with a first tunnel barrier layer, the first tunnel barrier layer arranged between the first conductivity type semiconductor layer and the substrate, and/or wherein the second junction structure is provided with a second tunnel barrier layer, the second tunnel barrier layer arranged between the second conductivity type semiconductor layer and the substrate.

17. The method according to claim 14, wherein at least one of the first junction structure and the second junction structure comprises an epitaxial Si layer, the first conductivity type semiconductor layer being the epitaxial Si layer and the substrate, and/or the second conductivity type semiconductor layer being the epitaxial Si layer.

18. The method according to claim 14, wherein the first conductivity type is p-type, the first conductivity type semiconductor layer comprises p-type doped amorphous hydrogenated silicon, p+a-Si: and the first dielectric layer comprises hydrogenated silicon nitride, SiNx:H, the p+a-Si:H layer being covered by the SiNx:H layer.
